(19) United States
(12) Patent Application Publication
(10) Pub. No.: US 2021/0391303 A1
(43) Pub. Date: Dec. 16, 2021

(54) SEMICONDUCTOR DEVICE

(71) Applicant: MACRONIX INTERNATIONAL CO., LTD., Hsinchu (TW)

(72) Inventor: Hsiang-Lan Lung, Kaohsiung City (TW)

(21) Appl. No.: 16/899,747

(22) Filed: Jun. 12, 2020

(51) Int. Cl. H01L 25/065; H01L 23/538; G11C 14/00; H01L 23/00

(52) U.S. Cl. CPC H01L 25/0657; H01L 23/5384; H01L 24/14; H01L 23/5386; G11C 14/0018; H01L 23/5385

(57) ABSTRACT

A semiconductor device includes a package substrate and at least one stacked structure. The package substrate has an upper surface. The stacked structure is disposed on the upper surface of the package substrate, and the stacking direction of the stacked structure is perpendicular to the upper surface. The stacked structure includes at least one non-volatile memory die, at least one dynamic random access memory die, and at least one memory control die.

### BACKGROUND OF THE INVENTION

### Field of the Invention

The present invention relates to a semiconductor device, and more particularly, to a semiconductor device including a non-volatile memory die.

### Description of the Related Art

With the increase of high-bandwidth requirements, common graphic memories (such as Graphics Double Data Rate, GDDR) can no longer keep up with the performance growth of processors (such as graphics processors (GPUs) and central processing units (CPUs)). The development of the high-bandwidth memory has become more and more urgent. However, the current high-bandwidth memory still has the problem of excessive power consumption. Therefore, there is an urgent need to develop a high-bandwidth memory capable of reducing power consumption.

### SUMMARY OF THE INVENTION

The present invention relates to a semiconductor device, wherein the semiconductor device includes at least one stacked structure. The stacked structure includes at least one non-volatile memory die, at least one dynamic random access memory die, and at least one memory control die. Since a non-volatile memory die consumes less power than a dynamic random access memory die, the semiconductor device of the present invention has an advantage of lower power consumption in comparison with a comparative example in which the stacked structure is composed of dynamic random access memory dies.

According to an aspect of the present invention, a semiconductor device is provided. The semiconductor device includes a package substrate and at least one stacked structure. The package substrate has an upper surface. The stacked structure is disposed on the upper surface of the package substrate, and the stacking direction of the stacked structure is perpendicular to the upper surface. The stacked structure includes at least one non-volatile memory die, at least one dynamic random access memory die, and at least one memory control die.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a perspective view of a semiconductor device according to an embodiment of the present invention.

FIG. 2 is a cross-sectional view taken along line A-A′ of FIG. 1 according to an embodiment of the present invention;

FIG. 3 is a cross-sectional view taken along line A-A′ of FIG. 1 according to another embodiment of the present invention.

### DETAILED DESCRIPTION OF THE INVENTION

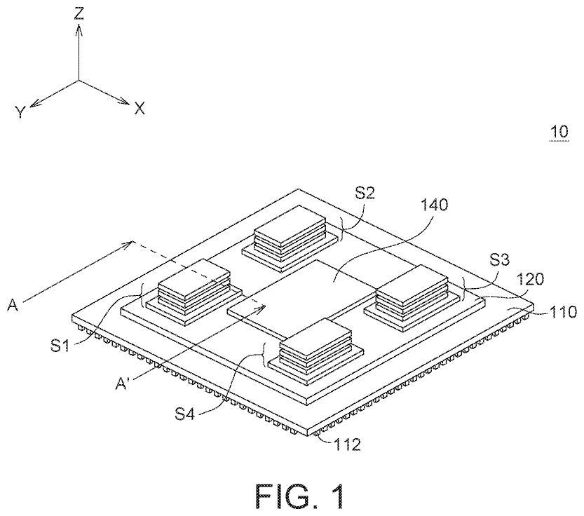

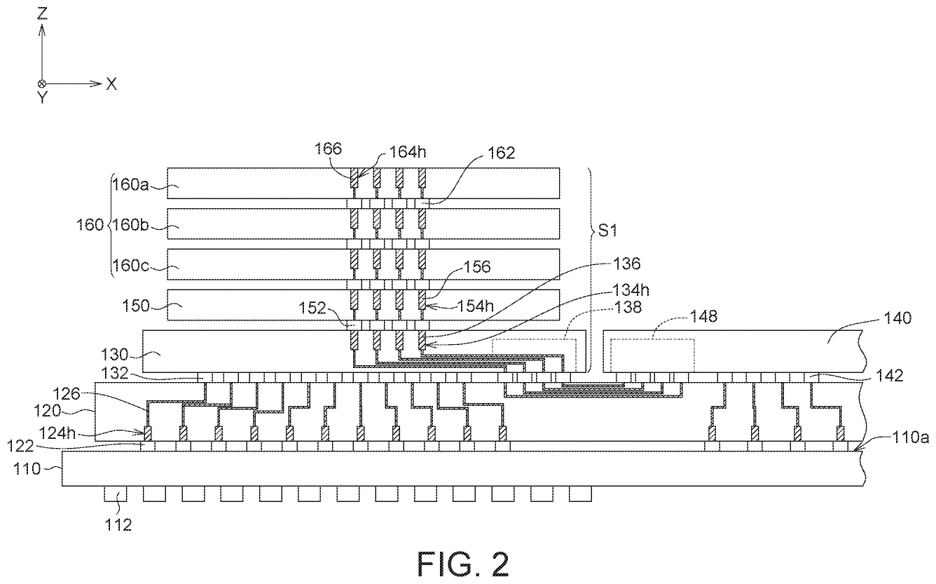

FIG. 1 is a perspective view of a semiconductor device 10 according to an embodiment of the present invention. FIG. 2 is a cross-sectional view taken along line A-A′ of FIG. 1 according to an embodiment of the present invention.

Referring to FIGS. 1 and 2, the semiconductor device 10 includes a package substrate 110, an interposer 120, stacked structures S1 to S4, and a processor 140. The package substrate 110 has an upper surface 110a. The interposer 120, the stacked structures S1 to S4, and the processor 140 are all disposed on the upper surface 110a. More specifically, the interposer 120 is disposed on the upper surface 110a of the package substrate 110, and the stacked structures S1 to S4 and the processor 140 are disposed on the interposer 120. In other words, the interposer 120 is disposed between the package substrate 110 and the stacked structures S1 to S4.

In some embodiments, a plurality of solder balls 112 are disposed on a lower surface of the package substrate 110 opposite to the upper surface 110a, so as to electrically connect the package substrate 110 to other electronic components (not shown).

The interposer 120 is, for example, a silicon interposer, but the invention is not limited thereto. The interposer 120 includes a plurality of connection vias 124h, and a plurality of bottom conductive elements 126 are disposed in the connection vias 124h. A plurality of micro-bumps 132 are disposed on the upper surface of the interposer 120. A plurality of bottom bumps 122 are disposed below the lower surface of the interposer 120. Portions of bottom conductive elements 126 can electrically connect the memory control die 130 to the package substrate 110. Portions of the bottom conductive elements 126 can electrically connect the processor 140 to the package substrate 110. For example, the size of the micro-bumps 132 is smaller than the size of the bottom bumps 122. The micro-bumps 132 and the bottom bumps 122 are in electrical contact with the bottom conductive elements 126.

The stacked structures S1 to S4 are disposed on the upper surface 110a of the package substrate 110, and the stacking direction (for example, the Z direction) of the stacked structures S1 to S4 is perpendicular to the upper surface 110a. In the present embodiment, the number of the stacked structures S1 to S4 is 4, but the present invention is not limited to this, and it is designed according to requirements. As shown in FIG. 2, the stacked structure S1 may include 3 non-volatile memory dies 160, a dynamic random access memory die 150 and a memory control die 130.

The non-volatile memory die 160 includes a first non-volatile memory die 160a, a second non-volatile memory die 160b, and a third non-volatile memory die 160c. In the present embodiment, the number of the non-volatile memory dies 160 is 3, but the present invention is not limited thereto. In other embodiments, the number of non-volatile memory dies 160 may be 1 or greater than 1, such as 2 or 4. In some embodiments, the sizes of different non-volatile memory dies 160 may be the same or different.

In some embodiment, sizes of the non-volatile memory dies 160, the dynamic random access memory dies 150, and the memory control dies 130 are different from each other.

In the present embodiment, the number of the dynamic random access memory dies 150 is 1, but the present invention is not limited thereto. In other embodiments, the number of dynamic random access memory dies 150 is greater than 1, such as 2 or 3. In some embodiments, the sizes of the different dynamic random access memory dies 150 may be the same or different.

In the present embodiment, the number of the memory control dies 130 is 1, but the present invention is not limited thereto. In other embodiments, the number of the memory control dies 130 is greater than 1, such as 2 or 3. In some embodiments, the sizes of different memory control dies 130 may be the same or different.

In the present embodiment, the memory control die 130, the dynamic random access memory die 150, and the 3 non-volatile memory dies 160 may be sequentially stacked on the package substrate 110 and the interposer 120 along the normal direction of the upper surface 110a. The dynamic random access memory die 150 is disposed between the non-volatile memory die 160 and the memory control die 130. The non-volatile memory die 160 is disposed on a top portion of the stacked structure S1, the dynamic random access memory die 150 is disposed in a middle portion of the stacked structure S1, and the memory control die 130 is disposed in a bottom portion of the stacked structure S1. However, the stacking order of the memory control die 130, the dynamic random access memory die 150, and the non-volatile memory die 160 is not limited thereto, and may be adjusted according to requirements. In some embodiments, the dynamic random access memory die 150 may be disposed on the top portion or bottom portion of the stacked structure S1.

The memory control die 130 includes a plurality of third vias 134h and a first port 138, and a plurality of third conductive elements 136 are disposed in the third vias 134h. The first port 138 is, for example, disposed on a side of the memory control die 130 adjacent to the processor 140, but the present invention is not limited thereto. Portions of the micro-bumps 132 correspond to the first port 138, and portions of the micro-bumps 132 correspond to an area outside the first port 138. Portions of the third conductive elements 136 extend to the first port 138 and electrically contact the micro-bumps 132 corresponding to the first port 138 to be electrically connected to the processor 140. Portions of the third conductive elements 136 are in electrical contact with the micro-bumps 132 corresponding to areas outside the first port 138 and are electrically connected to the interposer 120 and the package substrate 110.

The dynamic random access memory die 150 includes a plurality of second vias 154h, and a plurality of second conductive elements 156 are disposed in the second vias 154h. The second conductive elements 156 are in electrical contact with the plurality of micro-bumps 132 disposed between the dynamic random access memory die 150 and the memory control die 130.

Each of the non-volatile memory dies 160 includes a plurality of first vias 164h, and a plurality of first conductive elements 166 are disposed in the first vias 164h. Further, the first conductive elements 166 in the first non-volatile memory die 160a are in electrical contact with the micro-bumps 162 disposed between the first non-volatile memory die 160a and the second non-volatile memory die 160b; the first conductive elements 166 in the second non-volatile memory die 160b are in electrical contact with the micro-bumps 162 disposed between the second non-volatile memory die 160b and the third non-volatile memory die 160c; the first conductive elements 166 in the third non-volatile memory die 160c are in electrical contact with the micro-bumps 162 disposed between the third non-volatile memory die 160c and the dynamic random access memory die 150.

The processor 140 includes a second port 148, and the first port 138 is electrically connected to the second port 148 through the interposer 120. In detail, the processor 140 is in electrical contact with the micro-bumps 142 disposed between the processor 140 and the interposer 120. Portions of the micro-bumps 142 correspond to the area of the second port 148 and are electrically connected to the interposer 120 and the package substrate 110. Portions of the micro-bumps 142 correspond to the second port 148 are electrically connected to the micro-bumps 132 corresponding to the first port 138 through the bottom conductive element 126 in the interposer 120.

In some embodiments, the non-volatile memory dies 160 may be a Phase Change Memory die (PCM die), a Magnetoresistive Random Access Memory die, MRAM die), Ferroelectric Random Access Memory die (FeRAM die) or other suitable memory dies.

In some embodiments, the dynamic random access memory die 150 can be used as a read buffer or a read/write buffer of the non-volatile memory die 160 in the vertical direction.

In some embodiments, the memory control die 130 is, for example, a logic die. The memory control die 130 can serve as a memory controller that transmits data between the dynamic random access memory die 150, the non-volatile memory die 160, and the processor 140.

In some embodiments, the memory control die 130 may control the non-volatile memory die 160 and the dynamic random access memory die 150, and may transmit the data of the non-volatile memory die 160 and the dynamic random access memory 150 to the first port 138 of the memory control die 130 through the conductive elements (for example, the first conductive elements 166, the second conductive elements 156, and the third conductive elements 136) in the vias (for example, the first via 164h, the second via 154h and the third via 134h) and the micro-bumps (for example, micro-bumps 132, 152, and 162), and the data are transmitted to the second port 148 through the micro-bumps 132, 142 and the conductive elements 126 in the interposer 120 for the processor 140 to process the data.

According to an embodiment of the present invention, an improved high-bandwidth memory is provided. For example, the bandwidth of each stacked structure (for example, stacked structures S1 to S4) may be greater than 100 GB/s. The non-volatile memory die 160, the dynamic random access memory die 150, and the memory control die 130 of the present invention are vertically stacked to become at least one stacked structure, so that the non-volatile memory die 160, the dynamic random access memory die 150 and the memory control die 130 are formed in the same package, and are electrically connected to each other through the conductive elements in the vias and the micro-bumps, so that the semiconductor device with the memory having a high read/write bandwidth and a high memory capacity can be achieved.

Since the non-volatile memory die 160 consumes less power than the dynamic random access memory die 150, the semiconductor device 10 of the present invention has the advantage of low power consumption in comparison with the comparative example which has a stacked structure consisted of dynamic random access memory dies.

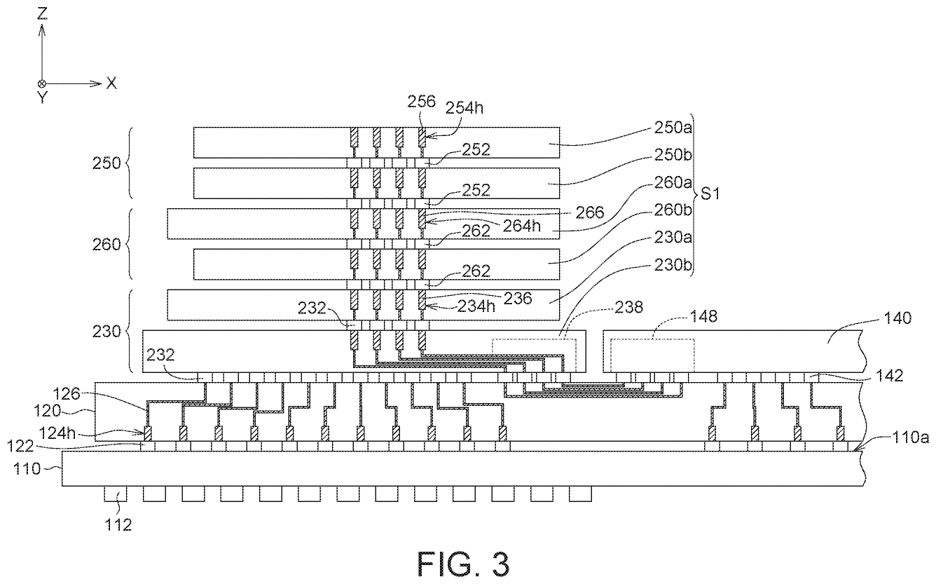

FIG. 3 is a cross-sectional view taken along line A-A′ of FIG. 1 according to another embodiment of the present invention, which is different from the embodiment of FIG. 2 in that the stacking order, number, and size of non-volatile memory dies 260, dynamic random access memory dies 250, and memory control dies 230 are different, and other identical or similar description will not be repeated.

Referring to FIG. 3, the stacked structure S1 may include 2 non-volatile memory dies 260, 2 dynamic random access memory dies 250 and 2 memory control dies 230. The memory control dies 230, the non-volatile memory dies 260, and the dynamic random access memory dies 250 are sequentially stacked on the interposer 120 and the package substrate 110 along the normal direction of the upper surface 110a of the package substrate 110. In other words, the dynamic random access memory dies 250 are disposed on the top of the stacked structure S1, and the non-volatile memory dies 260 are disposed between the dynamic random access memory dies 250 and the memory control dies 230.

The non-volatile memory dies 260 include a first non-volatile memory die 260a and a second non-volatile memory die 260b, and the first non-volatile memory die 260a and the second non-volatile memory die 260b may have different sizes. The dynamic random access memory dies 250 include a first dynamic random access memory die 250a and a second dynamic random access memory die 250b, and the first dynamic random access memory die 250a and the second dynamic random access memory die 250b may have different sizes. The memory control dies 230 include a first memory control die 230a and a second memory control die 230b, and the first memory control die 230a and the second memory control die 230b may have different sizes. It should be understood that the present invention is not limited thereto, and the stacking order, number, and size of the non-volatile memory die 260, the dynamic random access memory die 250, and the memory control die 230 can be adjusted according to requirements.

In some embodiment, sizes of the non-volatile memory dies 260, the dynamic random access memory dies 250, and the memory control dies 230 are different from each other

The memory control dies 230, the dynamic random access memory dies 250 and the non-volatile memory dies 260 are electrically connected to each other through the first conductive elements 266 in the first vias 264h of the non-volatile memory die 260, the first conductive elements 256 in the second vias 254h of the dynamic random access memory die 250, the third conductive elements 236 in the third vias 234h of the memory control die 230, and the micro-bumps 232, 252 and 262. For example, the memory control dies 230 may control the non-volatile memory dies 260 and the dynamic random access memory dies 250, and the data of the non-volatile memory dies 260 and the dynamic random access memory dies 250 may be transmitted to the first end port 238 of the memory control die 230 through the conductive elements (for example, the first conductive elements 266, the second conductive elements 256, and the third conductive elements 236) in the vias (for example, the first vias 264h, the second vias 254h, and the third vias 234h) and the micro-bumps (for example, micro-bumps 232, 252, and 262), and the data is then transmitted to second port 148 through the bottom conductive elements 126 in the micro-bumps 232, 142 and the interposer 120, for the processor 140 to process the data.

According to an embodiment of the present invention, a semiconductor device is provided. The semiconductor device includes a package substrate and at least one stacked structure. The package substrate has an upper surface. The stacked structure is disposed on the upper surface of the package substrate, and the stacking direction of the stacked structure is perpendicular to the upper surface. The stacked structure includes at least one non-volatile memory die, at least one dynamic random access memory die, and at least one memory control die. Since the non-volatile memory die consumes less power than the dynamic random access memory die, the stacked structure of the semiconductor device of the present invention includes not only the dynamic random access memory die but also the non-volatile memory die. Therefore, compared with the comparative example in which the stacked structure is consisted of dynamic random access memory dies, it has the advantage of low power consumption, so the power consumption can be reduced while the memory still has a high-bandwidth of read/write rate.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a package substrate having an upper surface, and
at least one stacked structure disposed on the upper surface of the package substrate, and a stacking direction of the at least one stacked structure is perpendicular to the upper surface,
wherein the at least one stacked structure comprises at least one non-volatile memory die, at least one dynamic random access memory die and at least one memory control die.

2. The semiconductor device according to claim 1, wherein a number of the at least one non-volatile memory die is greater than 1.

3. The semiconductor device according to claim 1, wherein a number of the at least one dynamic random access memory die is greater than 1.

4. The semiconductor device according to claim 1, wherein a number of the at least one memory control die is greater than 1.

5. The semiconductor device according to claim 1, wherein the at least one non-volatile memory die is disposed on a top portion of the at least one stacked structure.

6. The semiconductor device according to claim 5, wherein the at least one dynamic random access memory die is disposed between the at least one non-volatile memory die and the at least one memory control die.

7. The semiconductor device according to claim 1, wherein the at least one dynamic random access memory die is disposed in a top portion of the at least one stacked structure.

8. The semiconductor device according to claim 1, wherein the at least one non-volatile memory die is disposed between the at least one dynamic random access memory die and the at least one memory control die.

9. The semiconductor device according to claim 1, wherein the at least one non-volatile memory die comprises at least one first via, the at least one dynamic random access memory die comprises at least one second via, the at least one memory control die comprises at least one third via, wherein
at least one first conductive element, at least one second conductive element and at least one third conductive element are respectively formed in the at least one first via, the at least one second via and the at least one third via.

10. The semiconductor device according to claim 9, further comprising a plurality of micro-bumps, wherein the micro-bumps are disposed between the at least one non-volatile memory die, the at least one dynamic random access memory die, the at least one memory control die and the package substrate, to electrically connected to the at least one first conductive element, the at least one second conductive element and the at least one third conductive element.

11. The semiconductor device according to claim 10, further comprising:
an interposer disposed between the package substrate and the at least one stacked structure, wherein the interposer comprises a plurality of connection vias and a plurality of bottom conductive elements disposed in the connection vias, wherein portions of the micro-bumps are disposed on an upper surface of the interposer;
a plurality of bottom bumps disposed below a lower surface of the interposer; and
a processor disposed on the interposer.

12. The semiconductor device according to claim 11, wherein the memory control die comprises a first port, the processor comprises a second port, and the first port is electrically connected to the second port through the interposer.

13. The semiconductor device according to claim 11, wherein the at least one memory control die and the package substrate are electrically connected to each other by portions of the bottom conductive elements.

14. The semiconductor device according to claim 11, wherein the processor and the package substrate are electrically connected to each other by portions of the bottom conductive elements.

15. The semiconductor device according to claim 1, wherein sizes of the at least one non-volatile memory die, the at least one dynamic random access memory die, and the at least one memory control die are different from each other.
